(19) United States
(12) Patent Application Publication
(10) Pub. No.: US 2007/0227696 A1
(43) Pub. Date: Oct. 4, 2007

(54) Heat dissipating structure

(75) Inventors: Mao-Ching Lin, Taipei (TW); Win-Haw Chen, Taipei (TW)

Correspondence Address: EDWARDS ANGELL PALMER & DODGE LLP, P.O. BOX 55874, BOSTON, MA, 02205, US

(73) Assignee: Inventec Corporation

(21) Appl. No.: 11/394,975

(22) Filed: Mar. 30, 2006

(51) Int. Cl. H05K 7/20

(52) U.S. Cl. 165/80.3; 165/185; 361/704; 257/719

(57) ABSTRACT

A heat dissipating structure is proposed, which includes a frame, a heat dissipating element, and elastic elements. The frame encloses a central zone in which a heat generating element is disposed. The heat dissipating element has a bottom surface from which plates extend such that the heat dissipating element lies on the frame and covers the heat generating element disposed in the central zone of the frame. The elastic elements, each disposed on one of the plates, firmly secure the heat dissipating element to the frame by means of fasteners. Neither the elastic elements nor the fasteners screen the heat dissipating element and reduce the heat dissipation area thereof, thus overcoming a drawback of the conventional heat dissipating structure, that is, obstruction of the way of heat-dissipating currents.

### BACKGROUND OF THE INVENTION

1. Field of the Invention

This invention relates to a heat dissipating structure, and more particularly, to a heat dissipating structure for dissipating the heat generated by a heat generating element of an electronic device.

2. Description of Related Art

A CPU, the pivot of a computer, is in charge of computation and control and thus it is of vital importance. Operating at high frequencies, the CPU generates plenty heat which poses a potential risk to the computer system and thereby accounts for the emergence of heat dissipating devices.

Referring to FIG. 1, a known heat dissipating structure 1 for dissipating CPU-generated heat comprises a heat sink 11 fixed on a frame 12. The heat sink 11 includes a plurality of cooling fins for heat dissipation and is equipped with apertures 110 on two opposing sides thereof. Each of the apertures 110, coupled with an embedded screw 13 wrapped in a spring 14, screws the heat sink 11 to the frame 12. A heat generating element (not shown), such as a CPU, is installed beneath the frame 12. The heat dissipating structure 1 absorbs and dissipates the heat generated by the heat generating element.

However, the known heat dissipating structure has a problem of inefficient heat dissipation, that is, after screwing, the screw head blocks the way of heat-dissipating currents.

Furthermore, as laid down in the conventional technology, a heat sink is installed by means of a plurality of screwing structures, and the installation process is mostly manual; the screwing forces are unevenly exerted on screwing points, and in consequence the heat sink exerts pressure on the frame unevenly; given time, the screwing structures get loosened readily.

Hence, the aforesaid known disadvantages have to be addressed immediately.

### SUMMARY OF THE INVENTION

In view of the aforesaid known disadvantages, it is therefore an objective of the present invention to provide a heat dissipating structure which is timesaving and easy to use.

Another objective of the present invention is to provide a heat dissipating structure which maximizes the heat dissipating area of a heat dissipating element.

In order to achieve the above and other objectives, the present invention provides a heat dissipating structure which comprises a frame, a heat dissipating element, and elastic elements. The frame encloses a central zone in which a heat generating element is disposed. The heat dissipating element has a bottom surface from which plates extend such that the heat dissipating element lies on the frame and covers the heat generating element disposed in the central zone of the frame. The elastic elements, each disposed on one of the plates, firmly secures the heat dissipating element to the frame by means of fasteners. Neither the elastic elements nor the fasteners screen the heat dissipating element and reduce the heat dissipation area thereof.

The heat generating element is a member installed in an electronic device like a computer and selected from the group consisting of a CPU and a semiconductor package that generates heat while functioning. The heat dissipating element comprises a heat sink and a base supporting the heat sink. The heat sink comprises a plurality of cooling fins disposed in a row with slots formed therebetween to increase the heat dissipation area.

Preferably, the plates are integral with and protrude out of the base, and the plates extend from the base horizontally and outwardly. The fasteners are bolts, and the bolts are screwed into apertures and tapped holes installed on the fasteners, the plates and the frame respectively. Each of the elastic elements is a bending spring with two opposing ends formed into bifurcated holders for holding rivets fastened on the plate. A gap is formed between a rivet head of the rivet and the plate such that displacement of the bifurcated holder may take place within the gap whenever the fastener screws, to adjust pressure exerted on the bending spring.

The fastener is equipped with a stop member that limits the travel of the fastener deep down into the plate and controls the extent of insertion, to protect the fastener from any damage arising out of excessive insertion. Where the fastener is a bolt, the stop member is an annular stepped portion formed around the bolt.

Unlike a conventional heat dissipating structure wherein screwing structures screen the frontal area of a heat sink, the heat dissipating structure of the present invention maximizes the heat dissipating area of a heat dissipating element, as the heat dissipating element has a heat sink secured on a top surface of a base, whereas, upon completion of screwing, lying right below the top surface of the base are fasteners intended for screwing and elastic elements intended to screw the fasteners tightly.

Furthermore, as regards a conventional heat dissipating structure, a heat sink is secured on a frame only by means of a plurality of screws, thus the uninstallation/installation is complicated. By contrast, installation of the heat dissipating structure of the present invention can be achieved just by screwing a bolt on each of the two opposing sides.

Furthermore, since a conventional heat dissipating structure has a plurality of screwing structures, the screwing forces are unevenly exerted and thus the screwing structures get loosened readily. By contrast, each side of the heat dissipating structure of the present invention can be secured with a single screwing structure, and tighter screwing can be achieved with the spring.

Furthermore, since the fastener is equipped with a stop member for controlling the extent of insertion, the fastener is unlikely to be damaged because of excessive insertion of the bolt.

In conclusion, the heat dissipating structure of the present invention solves the known problems and enhances efficiency of heat dissipation, thereby having a great potential for industrial use.

### BRIEF DESCRIPTION OF DRAWINGS

FIG. 1 is a schematic diagram showing a known heat dissipating structure;

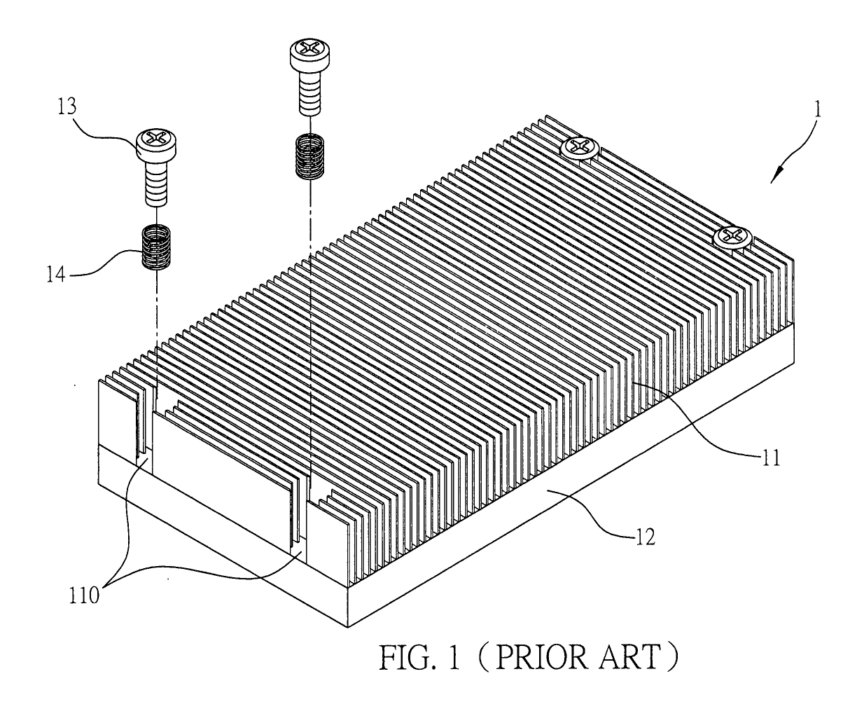

FIG. 2 is a schematic diagram showing a heat dissipating structure according to a preferred embodiment of the present invention;

FIG. 3 is a broken-out sectional view of a heat dissipating structure of the present invention; and

FIG. 4 is a structural drawing showing a fastener for fastening together a heat dissipating element and a frame regarding a heat dissipating structure of the present invention.

### DETAILED DESCRIPTION OF PREFERRED EMBODIMENTS

The following specific embodiments are provided to illustrate the present invention. Others skilled in the art will readily understand other advantages and functions of the present invention in accordance with the contents disclosed in this specification. The present invention can also be performed or applied by other different embodiments. Various modifications and changes based on different viewpoints and applications can be made in the details of the specification without departing from the spirit of the present invention. Points needing attention are as follows: all the accompany diagrams are simple schematic diagrams intended to schematically describe the basic structure of the present invention. Hence, in the diagrams, only those components related to the present invention are numbered, and the shown components are not drawn according to their actual quantity, shape and dimensions when implemented; in practice, the specifications and dimensions of the components are selectively devised indeed, and the layout of the components may be far more intricate.

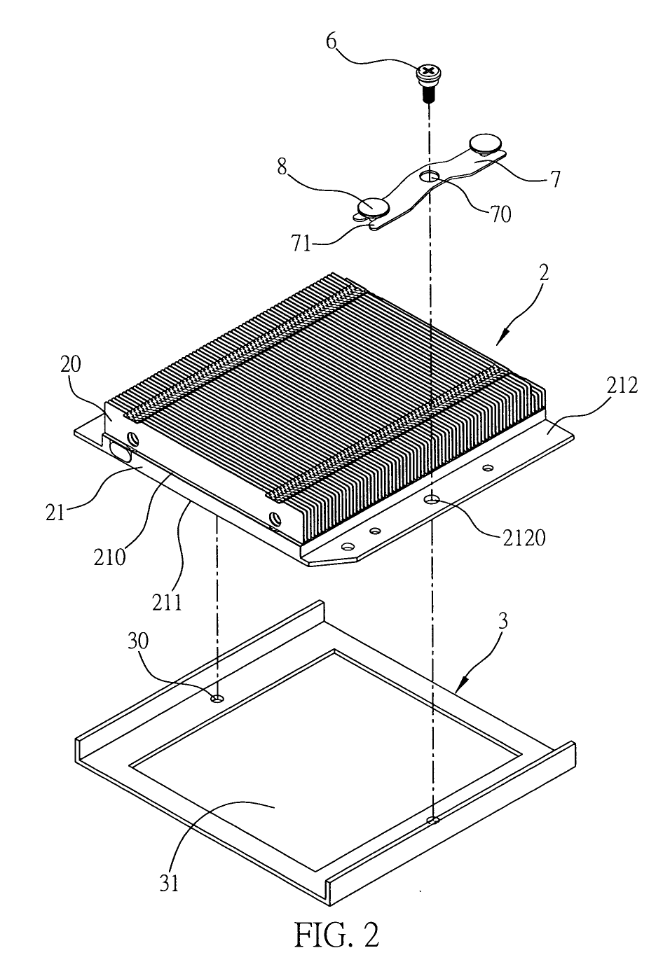

FIGS. 2 through 4 illustrate the technical features of the heat dissipating structure of the present invention with an embodiment. To avoid verbosity but keep the diagrams neat and tidy, only one member of any symmetrical pair of elements and devices of the embodiment is illustrated with a diagram and described.

Referring to FIG. 2, which is a schematic diagram showing a heat dissipating structure according to a preferred embodiment of the present invention. A heat dissipating structure of the present invention comprises a frame 3, a heat dissipating element 2, and elastic elements 7. A heat generating element (not shown) is disposed in a central zone 31 enclosed by the frame 3. The heat dissipating element 2 has a bottom surface from which plates 212 extend such that the heat dissipating element 2 lies on the frame 3 and covers the heat generating element disposed in the central zone 31 enclosed by the frame 3. Elastic elements 7 are disposed on the plates 212 and firmly secure the heat dissipating element 2 to the frame 3 by means of fasteners 6, wherein neither the elastic elements 7 nor the fasteners 6 screen the heat dissipating element 2 and reduce the heat dissipation area thereof.

The heat dissipating element 2 comprises a heat sink 20 and a base 21. The base 21 has a bottom surface 211 and a top surface 210, opposite to each other. The heat sink 20 is secured on the top surface 210. The heat generating element, which is disposed in the central zone 31 enclosed by the frame 3, is covered with the bottom surface 211. The frame 3 is provided with a plurality of fastening members 30 for matching and fastening the fasteners 6. The plates 212 are installed on the opposing sides of the bottom surface 211 of the base 21. Formed on the plates 212 are installation members 2120 which match the fastening members 30.

Formed on the elastic elements 7 are securing members 70 which match the installation members 2120. The fastener 6 connects the securing member 70 and the installation member 2120, and is fastened to the fastening member 30, so as to firmly fix the heat dissipating element 2 to the frame 3. Both the elastic elements 7 and the fasteners 6 lie below the top surface 210 of the base 21 of the heat dissipating element 2 and thus the heat dissipating area of the heat sink 20 of the heat dissipating element 2 is maximized.

The heat generating element is a member installed in an electronic device like a computer and selected from the group consisting of a CPU and a semiconductor package that generates heat while functioning.

The heat sink 20 comprises a plurality of cooling fins disposed in a row with slots formed therebetween to increase heat dissipation area.

The plates 212 are integral with and protrude out of the base 21; and the plates 212 extend from the base 21 horizontally and outwardly. The fasteners 6 are bolts. Both the installation members 2120 and the securing members 70 are apertures. The fastening members are tapped holes. The elastic element 7 is a bending spring with two opposing ends formed into bifurcated holders 71 for holding rivets 8 fastened on the plate 212, in order to secure the elastic element 7.

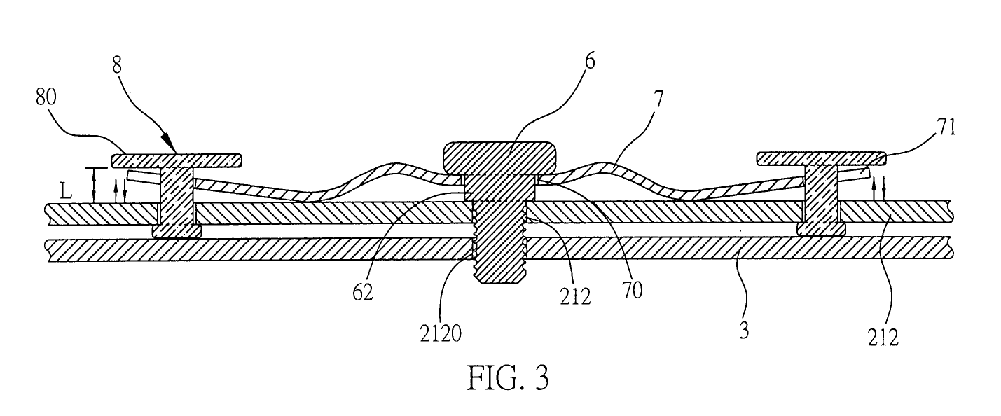

Referring to FIG. 3, a gap L is formed between a rivet head 80 of the rivet 8 and the plate 212 such that displacement of the bifurcated holder 71 may take place within the gap L whenever the fastener 6 screws, to adjust pressure exerted on the bending spring.

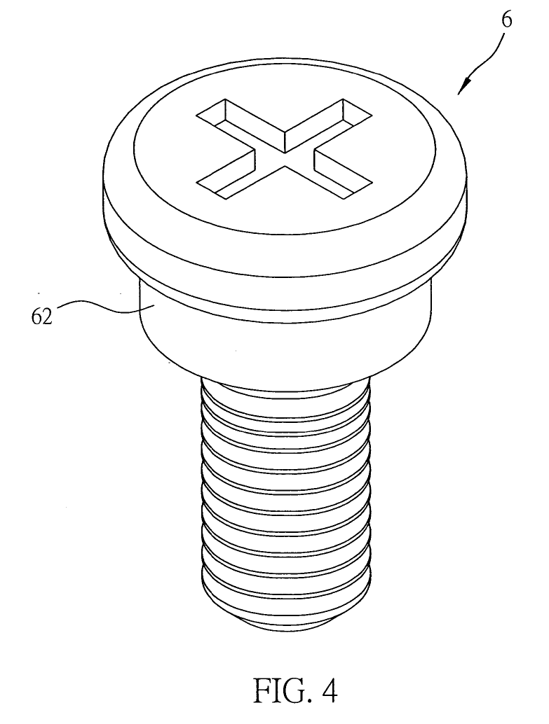

Referring to FIG. 4, the fastener 6 is further equipped with a stop member 62 which allows the fastener 6 to penetrate the securing member 70 and connect with the installation member 2120, limits the travel of the fastener 6 deep down into the plate 212, and controls the extent of insertion, to protect the fastener 6 from any damage arising out of excessive insertion. Where the fastener 6 and fastening member 30 are a bolt and a tapped hole respectively, the stop member 62 is an annular stepped portion formed around the bolt.

Unlike a conventional heat dissipating structure wherein screwing structures screen the frontal area of a heat sink, the heat dissipating structure of the present invention maximizes the heat dissipating area of a heat dissipating element, as the heat dissipating element has a heat sink 20 secured on a top surface 210 of a base 21, whereas, upon completion of screwing, lying right below the top surface 210 of the base 21 are fasteners 6 intended for screwing and elastic elements 7 intended to screw the fasteners 6 tightly.

Furthermore, as regards a conventional heat dissipating structure, a heat sink is secured on a frame only by means of a plurality of screws, thus the uninstallation/installation is complicated. By contrast, installation of the heat dissipating structure of the present invention can be achieved just by screwing a bolt on each of the two opposing sides.

Furthermore, since a conventional heat dissipating structure has a plurality of screwing structures, the screwing forces are unevenly exerted and thus the screwing structures get loosened readily. By contrast, each side of the heat dissipating structure of the present invention can be secured with a single screwing structure, and tighter screwing can be achieved with the spring.

Furthermore, since the fastener is equipped with a stop member for controlling the extent of insertion, the fastener is unlikely to be damaged because of excessive insertion of the bolt.

In conclusion, the heat dissipating structure of the present invention solves the known problems and enhances efficiency of heat dissipation, thereby having a great potential for industrial use.

The aforesaid embodiment is intended for illustration of the features and functions of the present invention rather than limiting the scope thereof. Hence, whatever equivalent changes and modifications finalized by means of the disclosures of the present invention without departing from the disclosed spirit and technical scope thereof should be covered by the appended claims.

What is claimed is:

1. A heat dissipating structure, comprising:
a frame for disposing a heat generating element in a central zone enclosed by said frame;
a heat dissipating element having a bottom surface from which plates extend such that said heat dissipating element lies on said frame and covers said heat generating element disposed in said central zone enclosed by said frame; and
elastic elements disposed on said plates and firmly securing said heat dissipating element to said frame by means of fasteners, wherein neither said elastic elements nor said fasteners screen said heat dissipating element and reduce heat dissipation area thereof.

2. The heat dissipating structure as recited in claim 1, wherein said heat generating element is a member selected from the group consisting of a CPU and a semiconductor package that generates heat while functioning.

3. The heat dissipating structure as recited in claim 1, wherein said heat dissipating element comprises a base equipped with a top surface and an opposing bottom surface, and a heat sink secured on said top surface of said base.

4. The heat dissipating structure as recited in claim 3, wherein said heat sink comprises a plurality of cooling fins disposed in a row with slots formed therebetween to increase heat dissipation area.

5. The heat dissipating structure as recited in claim 3, wherein said plates are integral with and protrude out of said base, and said plates extend from said base horizontally and outwardly.

6. The heat dissipating structure as recited in claim 1, wherein said fasteners are bolts, with installation members, securing members and fastening members being disposed on said plates, said elastic elements and said frame respectively to hold said fasteners, wherein both said installation members and said securing members are apertures, and said fastening members are tapped holes.

7. The heat dissipating structure as recited in claim 1, wherein each of said elastic elements is a bending spring with two opposing ends formed into bifurcated holders for holding rivets fastened on each of said plates.

8. The heat dissipating structure as recited in claim 7, wherein a gap is formed between a rivet head of said rivet and said plate such that displacement of said bifurcated holder may take place within said gap whenever said fastener screws, to adjust pressure exerted on said bending spring.

9. The heat dissipating structure as recited in claim 1, wherein said fastener is equipped with a stop member that limits travel of said fastener deep down into said plate and controls the extent of insertion.

10. The heat dissipating structure as recited in claim 9, wherein said fastener is a bolt, and said stop member is an annular stepped portion formed around said bolt.
